(19) United States
(12) Patent Application Publication
(10) Pub. No.: US 2017/0358698 A1
(43) Pub. Date: Dec. 14, 2017

(54) AMORPHOUS COPOLYESTER-BASED MATERIAL IN A PHOTOVOLTAIC MODULE

(71) Applicant: Soliculture, Inc., Scotts Valley, CA (US)

(72) Inventors: Melissa OSBORN, Aptos, CA (US); Ingrid ANDERSON, Soquel, CA (US)

(21) Appl. No.: 15/179,749

(22) Filed: Jun. 10, 2016

(51) Int. Cl. H01L 31/049; H01L 31/18; C08J 5/18; H01L 31/0236

(52) U.S. Cl. CPC H01L 31/049; H01L 31/02366; H01L 31/18; C08J 5/18; C08J 2367/03

(57) ABSTRACT

The invention relates to the use in a photovoltaic module of a monolayer film as a backsheet, this composition comprising, with respect to the total weight of the composition from 50 to 100% of amorphous copolyester. The invention further comprises a backsheet of the amorphous copolyester film with two optional films adhered to it, an adhesion promoting film and an anti-weathering film. The invention further encompasses a photovoltaic module comprising the backsheet composition, and an optional scrim layer, according to the invention.

### BACKGROUND OF INVENTION

This disclosure relates to solar modules, and in particular, backsheets and related materials for solar modules, more particularly, crystalline silicon solar modules and to solar modules containing backsheets. The backsheets are based on a single layer, or monolayer, film that is composed primarily of an amorphous copolyester compound. The backsheets may contain one or two optional films in addition to the amorphous copolyester film. Of course, there can be other variations, modifications, and alternatives.

Widespread use of conventional solar modules for electricity generation is expanding rapidly. Solar modules are composed of solar cells that are electrically connected and encapsulated. Wafer-based silicon solar cells can contain monocrystalline silicon (c-Si), poly- or multi-crystalline silicon (poly-Si or mc-Si), and are generally about 180 to 240 μm in thickness. Wafer-based solar cells can be monofacial, collecting light on one face, or bifacial, collecting light on both faces, where one light-receiving side has a higher efficiency than the other light-receiving side. Typically, a series of wafers are soldered together with electrical tabbing wires, to form a layer of solar cells. The solar cell layer may further comprise electrical tabbing wires connecting the individual cell units to electrical bus bars that have one end connected to the solar cells and the other exiting the module. The bus wires that exit the module are electrically connected to a junction box, which is adhered to the module. The layer of solar cells is laminated to encapsulant layer(s) and protective layer(s) to form a weather-resistant module. In general, a solar cell module derived from wafer-based solar cell(s) comprises, in order of position from the front light-receiving side, or highest efficiency light-receiving side, to the back non-light-receiving side: a top layer, a top encapsulant layer, a solar cell layer, a back encapsulant layer, and a back layer.

Although effective, an improved solar module is highly desired.

### SUMMARY OF INVENTION

This disclosure relates to solar modules, and in particular, backsheets and related materials for solar modules, more particularly, crystalline silicon solar modules and to solar modules containing backsheets. The backsheets are based on a single layer, or monolayer, film that is composed primarily of an amorphous copolyester compound. The backsheets may contain one or two optional films in addition to the amorphous copolyester film. Of course, there can be other variations, modifications, and alternatives.

In an example, the present invention provides a photovoltaic module of a monolayer film as a backsheet, this composition comprising, with respect to the total weight of the composition from 50 to 100% of amorphous copolyester. The invention further comprises a backsheet of the amorphous copolyester film with two optional films adhered to it, an adhesion promoting film and an anti-weathering film. The invention further encompasses a photovoltaic module comprising the backsheet composition according to the invention.

Instead of having separated top and back encapsulating layers there may also be just one encapsulating layer, which then incorporates the layer of solar cells.

The top layer is designed to provide rigidity, protection from the environment, and high transmission in order to allow light to pass to the solar cell layer. The top layer is typically a glass sheet. In an alternative configuration, the top layer can be composed of a sheet of clear acrylic, fluoropolymer or other polymer-based composition.

The encapsulant layers are designed to encapsulate and protect the solar cell layer from mechanical, as well as adhere them to the top and back layers. Typical encapsulant layers include ethylene vinyl acetates (EVA) polymers. Other encapsulant layers include polyvinyl butyral (PVB), thermoplastic polyurethane (TPU), or ionomer polymers.

The back layer is a protective backsheet. The backsheet typically provides electrical insulation of the solar module and protects the solar module from influences from the environment, predominantly from moisture. In prior art, usually multiple layers of materials are needed in order to achieve all of these attributes. Each individual layer alone is not capable of providing all the necessary characteristics. For instance, the core layer is used for electrical insulation, which is often low-cost semi-crystalline PET. This PET core does not stand up to long-term environmental exposure because of its semi-crystalline nature. Heat and moisture over time causes the semi-crystalline film to become brittle and hazy¹. Therefore, a separate layer is added to provide protection from moisture ingress. This thin outer layer, often a fluoropolymer or PE with considerable anti-weathering additives, is an additional cost. In addition to the added cost of materials for multiple layers, the individual layers cannot be combined to a multi-layer backsheet in a single process step but instead must be separately and subsequently bonded together, which further increases processing costs. Furthermore, the “tie-layers” that are used to bond multiple layers together often suffer from poor stability, causing inter-layer adhesion concerns during in-field environmental exposure. Delamination of the backsheet layers of a solar module during its operational life is a great safety concern. In this disclosure, the backing layer is typically a robust amorphous copolyester monolayer film. This film alone can provide all of the needs listed above, namely electrical insulation, mechanical stability, and protection from the environment. Because the copolyester is composed of material that does not recrystallize after exposure to heat and moisture, the film does not require additional anti-weathering layers. Thus, cost is comparably lower, while still meeting the required characteristics of a solar module backsheet.

The following list of exemplary embodiments illustrates various specific features, advantages, and other details of the invention. The particular materials and amounts recited in these exemplary embodiments, as well as other conditions and details, should not be construed in a manner that would limit the scope of this invention.

### BRIEF DESCRIPTION OF THE DRAWINGS

FIG. 1 shows a simplified representative x-ray diffraction spectrum of an amorphous copolyester material used in the monolayer backsheet provided herein in an example.

FIG. 2 shows a simplified representative x-ray diffraction spectrum of a semi-crystalline polyester material as a counter example to the amorphous copolyester material composition described herein.

FIGS. 3A-3D contain four images comparing amorphous and semi-crystalline polyester-based films in an example.

FIGS. 4A and 4B show images of two polyester-based films of equal thickness, after prolonged exposure to heat and moisture in an example.

FIG. 5 shows a simplified schematic cross-section of a solar module as described in an example of the invention.

FIG. 6 shows an embodiment of the monolayer backsheet provided herein in an example.

FIG. 7 shows a simplified illustration of an embodiment of the backsheet provided herein with one optional films adhered to the amorphous copolyester film as described above in an example.

FIG. 8 shows a simplified illustration of an embodiment of the backsheet provided herein with two optional films adhered to the amorphous copolyester film as described above in an example.

FIGS. 9, 10, and 11 illustrate plots of parameters of the backsheet in examples of the present invention.

### DETAILED DESCRIPTION OF EXAMPLES

Before any embodiments of this disclosure are explained in detail, it is to be understood that the disclosure is not limited in its application to the details of construction and the arrangement of components set forth in the following description. The invention is capable of other embodiments and of being practiced or of being carried out in various ways. Also, it is to be understood that the phraseology and terminology used herein is for the purpose of description and should not be regarded as limiting.

As used herein, the terms “comprises,” “comprising,” “includes,” “including,” “containing,” “characterized by,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus and including equivalents. Further, unless expressly stated to the contrary, “or” refers to an inclusive or and not to an exclusive or.

As used herein, the term “consisting of” is meant to be limiting and include only the specified materials or steps and their equivalents.

The use of “a” or “an” is meant to encompass “one or more”.

Any numerical range recited herein is intended to include and to specifically disclose the end points specified and also all integers and fractions within that range. For example, a range of from 1% to 50% is intended to be an abbreviation and to expressly disclose the values 1% and 50% and also the values between 1% and 50%, such as, for example, 2%, 40%, 10%, 30%, 1.5%, 3.9% and so forth.

The term “copolyester” is used to refer to polyesters (combinations of diacids and diols), which have undergone some kind of modification.

The term “amorphous” is used to refer to a solid that lacks crystallinity.

The present disclosure provides protective sheets (i.e. backsheets) for the back layer of solar modules, which is the side of a solar module that is opposite to its light-receiving side, or, when bifacial solar cells are used, the back layer is the side of the solar cell layer that has a lower efficiency. The present disclosure also provides solar modules comprising these backsheets and methods of making them.

The backsheets provide electrical insulation. Typically, the backsheets have a dielectric breakdown voltage of at least 8-15 kV. The backsheets also provide mechanical protection of the solar module. Typically, the backsheets have a tensile strength of at least 90 MPa and thermal shrinkage of less than 5%. The backsheets also provide adhesion to the encapsulant layer of the solar module. Typically, the backsheets have an adhesion between the encapsulant and the backsheet layers of at least 3 N/mm. A particular advantage of the backsheets provided herein is that they provide long-term electrical and mechanical protection against heat and moisture exposure, and their adhesion properties are maintained after prolonged heat and moisture exposure. It has been found that the mechanical, electrical, and adhesion properties of the backsheets provided herein do not degrade or only degrade to a comparatively low degree after exposure to extreme heat and moisture conditions, like 1000 hours exposure to 85° C. and 85% humidity as described, for example, in the experimental results section.

The protective sheet materials (backsheets) may provide optical clarity, for example, when bifacial solar cells are used in solar modules. The backsheets provided herein do not degrade significantly with respect to optical transmission properties, when exposed to UV light. It has been found that the optical transmission properties of the backsheets provided herein do not degrade or only degrade to a comparatively low degree after exposure to extreme UV conditions, like 25 year equivalent of outdoor exposure as described, for example, in the experimental section. An additional feature of the amorphous copolyester film is that it does not re-crystallize after prolonged exposure to heat and moisture. This is contrary to a film of semi-crystalline polyester composition, which becomes hazy as the material becomes more crystalline.

In one embodiment the backsheets have a total thickness of about 150 microns mm to about 700 microns, or from about 200 microns mm to about 350 microns. It is an advantage of the present disclosure that the backsheets with a minimal thickness may already provide all or at least some of the necessary properties as described above and below.

In one embodiment, the backsheets can have a single-layer structure, or so-called monolayer structure, in which an amorphous copolyester film is the lone layer of the backsheet. The single layer is referred to herein as a “monolayer backsheet” by which is meant that this layer provides all of the protective properties of the backsheet, as described above and below.

In another embodiment, the backsheets can have a two-layer structure, or so-called bi-layer structure, in which an amorphous copolyester film is adhered to an optional adhesion promoting film. The adhesion promoting film may be comprised of a copolymer blend of EVA and PE as its main component. The film may contain additional additives, such as UV absorbers, flame-retardants, colorants, or other materials.

In yet another embodiment, the backsheets can contain a second optional layer that is adhered to the amorphous copolyester to increase anti-weathering properties. This optional film can be comprised of robust polyester, such as polyethylene naphthalate (PEN), or fluoropolymer as its main component. Suitable fluoropolymers may include PVD, PVDF, ETFE, or others. The film may contain additional additives, such as UV absorbers, flame-retardants, colorants, or other materials. The backsheets can contain the core amorphous copolyester film, the adhesion promoted film described above, and the anti-weathering film, to create a tri-layer backsheet.

The monolayer backsheet may be surface treated on one or more sides. Surface treatment may be carried out to improve the compatibility or adhesion to another surface or to provide a functional or decorative pattern or structure.

The monolayer backsheet may have smooth or rough surfaces on one or both of its external sides. Rough surfaces may facilitate adhesion to the encapsulant layer during the lamination process when the backsheet is included in a solar cell module. Rough surfaces can be created by mechanical embossing or by melt fracture during extrusion of the sheets followed by quenching so that surface roughness is retained during handling.

The monolayer backsheet contains amorphous copolyester as its major component. “Major component” denotes that this component is present at the highest amount as expressed by percentage by weight based on the weight of the layer. Amorphous copolyester is present in an amount of greater than 50% by weight or more preferably even greater than 75% by weight or more preferably even greater than 90% by weight. The weight percentages are based on the weight of the film they are contained in.

The amorphous copolyester resin may have a Vicat softening temperature of at least 85° C., but less than 160° C. This range of softening temperatures may facilitate adhesion to the encapsulant layer during the lamination process when the backsheet is included in a solar cell module.

Examples of suitable amorphous copolyester resins may include, but are not limited to, polyethylene terephthalate glycol-modified with less than 50% of the diol content is cyclohexane dimethanol (PETG), polyethylene terephthalate glycol-modified with more than 50% of the diol content is cyclohexane dimethanol (PCTG), copolyester made from the monomer terephthalic acid (TPA) and the co-monomer cyclohexanedimethanol (CHDM) and the aliphatic monomer tetramethylcyclobutanediol (TMCD), or amorphous polyethylene terephthalate (APET). Molecular weight of said resins may be greater than 1×10⁶ g/mole, usually between 3.1 and 5.7 million g/moles.

The backsheet may have a total thickness effective to provide the electrical breakdown voltage of at least 8-15 kV and to provide some or all of the mechanical properties as described herein. Typically a total backsheet thickness of at least 210 μm or at least 310 μm may be sufficient.

The monolayer backsheet will now be described in greater detail.

### Monolayer Backsheet:

If incorporated into a solar module, the monolayer backsheet may be the outermost layer of the solar cell module. This layer protects the solar module from the environment. The layer may or may not be surface treated to create a pattern or structure or roughened surface as described above. If incorporated into a solar module, the monolayer backsheet is in direct contact with the back encapsulant layer of the solar module.

The monolayer backsheet provides electrical insulation. Thus, the amorphous copolyester film has sufficient thickness to provide a dielectric breakdown voltage of this backsheet of at least 8 kV. Typically the film has a thickness of at least 210 μm or at least 310 μm or at least 350 μm. The upper limit of this film is determined by material costs and the necessary mechanical properties of the backsheet and is typically less than 700 μm.

The monolayer backsheet typically comprises the amorphous copolyester film described above. The film may contain, for example, up to about 10 wt %, or preferably up to about 5 wt %, or more preferably up to about 1 wt % of antioxidants based on the total weight of the film. In addition or instead of antioxidants, the film may contain, for example, up to about 10 wt %, or preferably up to about 5 wt %, or more preferably up to about 1 wt % of UV-stabilizers based on the total weight of the film. In addition or instead of antioxidants and/or UV-stabilizers the film (ii) may contain anti-dripping agents up to about 10 wt %, or preferably up to about 5 wt %, or more preferably up to about 1 wt % of based on the total weight of the film.

The amorphous copolyester film can be loaded to up to 20% or up to 30% by weight with flame retardants and/or anti-dripping agents, which can provide anti-flammability characteristics, while still providing the necessary protective properties as described above and below.

The amorphous copolyester film provided herein can be loaded with colorant to up to 10% or more preferably up to 3% or more preferably up to 1% by weight of the film. A colorant can be a dye, pigment, luminescent or reflective material. A colorant, preferably a reflective material, may be added to the film in order to achieve a white, reflective appearance. Alternatively, a colorant may be added to the film in order to achieve a black appearance. Alternatively, a colorant may be added to the film in order to achieve a colored appearance that is not black or white. A luminescent material may be added to the film in order to alter the light spectrum passing through the monolayer backsheet or solar module.

### UV Absorbers:

Typical examples of UV absorbers include but are not limited to triazines, benzotriazoles, hydroxybenzophenones, hydroxyphenyltriazines, esters of benzoic acids, and mixtures of two or more thereof. Further examples include cyclic amines. Examples include secondary, tertiary, acetylated, N-hydrocarbyloxy substituted, hydroxy substituted N-hydrocarbyloxy substituted, or other substituted cyclic amines which are further characterized by a degree of steric hindrance, generally as a result of substitution of an aliphatic group or groups on the carbon atoms adjacent to the amine function.

### Flame Retardants:

Flame-retardants are compounds that reduce or prevent flame propagation or increase the inflammability of a material. Examples of flame-retardants include but are not limited to halogenated aromatic compounds, like halogenated biphenyls or biphenyl ethers and bisphenols. Typically the halogenated materials are brominated or polybrominated. Specific examples include bisphenols like polybrominated biphenyl, penta-, octa and deca deca-brominated diphenyl ethers (BDE's), tetrabromobisphenol-A (TBBPA).

Further examples include but are not limited to inorganic compounds like alumina trihydrate, antimony oxide, magnesium hydroxide, zinc borate, organic and inorganic phosphates, red phosphor and combinations thereof.

### Anti-Dripping Agents:

Anti-dripping agents are substances that reduce or prevent dripping of a polymer when being exposed to a flame. Typically, dripping agents include fluoropolymer, such a polytetrafluoroethene polymers and copolymers. The dripping agents may be dispersed in or blended with the polymer making up the respective layer. Commercial examples of dripping agents include MM5935EF from Dyneon LLC, ALGOFLON DF210 from Solvay-Solexis or ENTROPY TN3500 from Shanghai Entropy Chemical.

### Colorants:

Pigments may be inorganic or organic. Pigments may be of green, blue, red, pink, purple and white color. Most commonly used white pigments are inorganic pigments, and examples include but are not limited to titanium oxides (TiO₂), barium sulfate, barium titanate (BaTiO₃), strontium titanate (SrTiO₃), calcium titanate (CaTiO₃), calcium carbonate, lead titanate (PbTiO₃), zinc oxide, zinc sulfate, magnesium oxide or aluminum oxide. Examples of black pigments include but are not limited to iron oxide, complex metal oxide; a metal salt or various kinds of organic pigments. The pigments may be dispersed, blended or dissolved in the layer but may be painted or printed onto a layer. Reflective materials include glass particles or metal particles, with glass particles being preferred. They may be dispersed, blended or dissolved in a layer.

### Solar Modules:

The invention further provides a solar cell module comprising at least one backsheet as described above.

A solar module comprises at least one layer of solar cells. Solar cells can be either monofacial or bifacial, where the monofacial solar cells have a light-receiving side and a side opposite to it, which is referred to as the non-light-receiving side. Alternatively, the solar cells can have light-receiving sides on both planes of the wafer, so-called bifacial. The bifacial solar cells have one light-receiving side that is higher efficiency than the other light-receiving side. Preferably, the solar cells are electrically interconnected with tabbing ribbons, forming a solar cell layer. In addition, the solar cell layer may further comprise electrical bus bars, where one end is connected to the solar cells and one end exits the module, via a junction box.

The term “solar cell” is meant to include any article that can convert light into electrical energy, preferably wafer-based silicon solar cells (e.g., c-Si or mc-Si).

The solar module is further comprised of one or more encapsulant layers. The solar module contains at least one encapsulant layer or a part of an encapsulant layer adjacent to the light-receiving side of the solar cell layer, or the higher efficiency side of the bifacial solar cell layer, where bifacial wafers are used. Another encapsulant layer or part of the encapsulant layer is adjacent to the non-light-receiving side of the solar cell layer, or the lower efficiency side of the bifacial solar cell layer when bifacial wafers are used. Preferably, the encapsulant layer comprises poly(ethylene vinyl acetates) (EVA). Alternatively, the encapsulant layer may comprise any suitable polymeric material, for examples acid copolymers, ionomers, poly(ethylene vinyl acetates), poly(vinyl acetals), polyvinyl butyral (PVB), thermoplastic polyurethane (TPU), ionomer polymers, polyurethanes, poly(vinyl chlorides), polyethylenes (e.g., linear low density polyethylenes), polyolefin block elastomers, copolymers of an α-olefin and an α,β-ethylenically unsaturated carboxylic acid ester (e.g., ethylene methyl acrylate copolymer and ethylene butyl acrylate copolymer), silicone elastomers, epoxy resins, and combinations of two or more thereof.

The backsheets described is this invention are laminated to the non-light-receiving part of the encapsulant layer (or part thereof) facing the non light-receiving side of the solar cells, or in the case of a bifacial solar cell layer, the backsheet is laminated facing the lower efficiency light-receiving side of the solar cells.

In an alternate configuration, a scrim layer may be laminated between the solar cell layer and the backsheet of a solar module. The scrim layer is designed to improve manufacturability. The scrim layer may eliminate air bubbles during lamination, hold solar cells and wiring in place, and prevent deformation of the encapsulation and backsheet layers. The scrim may be comprised of glass fibers, polyester (PET), polyphenylene sulfide (PPS) or bicomponent fibers.

The solar cell module may further comprise a top layer serving as the outermost layer of the module on the light-receiving side, or the highest efficiency light-receiving side when bifacial solar cells are used. The top layer may be formed of any suitable transparent sheets or films. Suitable sheets may be glass or plastic sheets, such as polycarbonates, acrylic polymers, polyacrylates, cyclic polyolefins, polystyrenes, polyamides, polyesters, fluoropolymers, or combinations of two or more thereof. Preferably, the top layer is made of glass, or more preferably, low-iron glass to increase light transmission. The term “glass” includes not only window glass, plate glass, silicate glass, sheet glass, low iron glass, tempered glass, tempered CeO-free glass, and float glass, but also colored glass, specialty glass, coated glass, and textured glass.

In manufacturing solar cell modules, the component layers may be stacked in the appropriate order to form a pre-lamination assembly. The pre-lamination assembly may then be placed into a laminator where a vacuum environment is attained. While under vacuum, sufficient pressure and heat may be applied in order to achieve a laminated product. The assembly is heated to at least 130° C. or preferably at least 135° C. or more preferably at least 140° C. Pressure of at least 50 kPa or preferably at least 80 kPa or more preferably at least 100 kPa is applied to the assembly. During the lamination of the solar module, a texture may be transferred from a Teflon release sheet unto the outermost surface of the backsheet as described in this invention.

The backsheets are now further illustrated by referring to the figures and related descriptions.

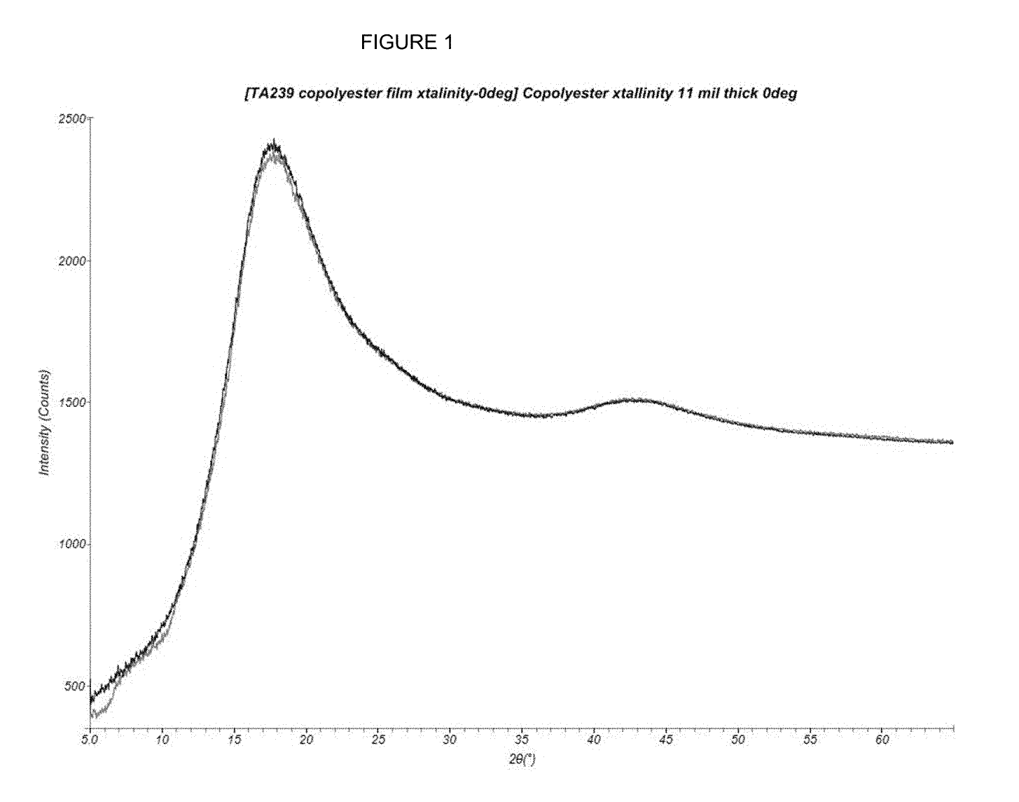

FIG. 1 shows a representative x-ray diffraction spectrum of an amorphous copolyester material used in the monolayer backsheet provided herein. Copolyester film was scanned at 0° (black) and 90° (gray) rotation to check for directional crystallinity.

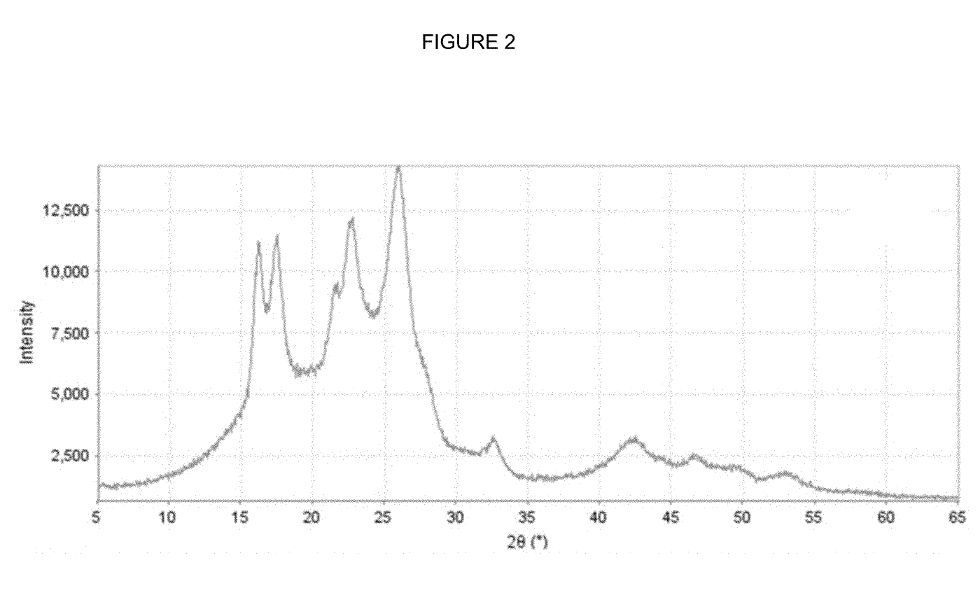

FIG. 2 shows a representative x-ray diffraction spectrum of a semi-crystalline polyester material as a counter example to the amorphous copolyester material composition described herein.

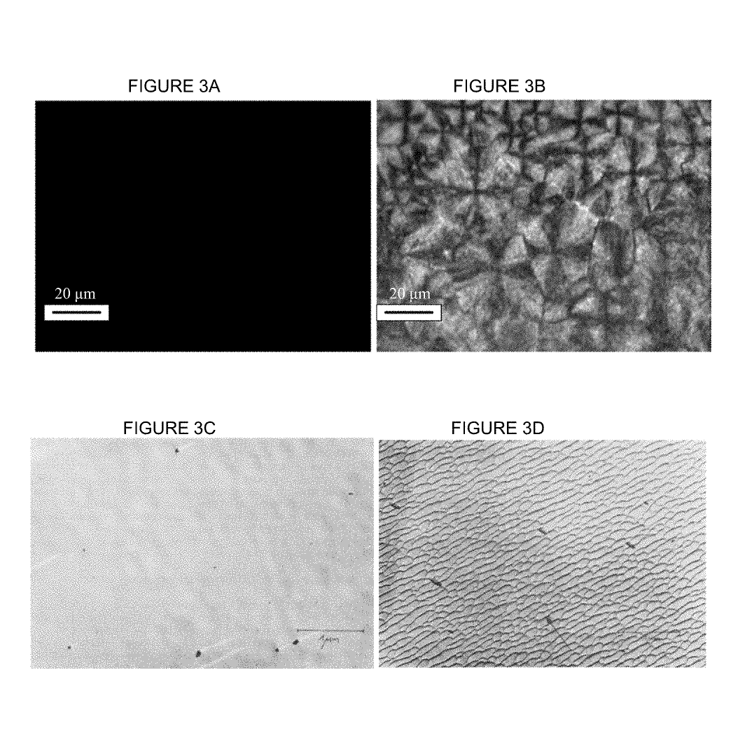

FIGS. 3A-3D contain four images comparing amorphous and semi-crystalline polyester-based films. FIGS. 3A and 3B are representative polarizing optical micrographs showing the birefringence of (A) an amorphous copolyester film, such as those described herein, and (B) a semi-crystalline polyester film, as a counter example. There is a space-filling spherulitic superstructure evident in the birefringence of the semi-crystalline polyester film, which is not apparent in the amorphous copolyester film. FIGS. 3C and 3D are scanning electron microscope (SEM) images of (C) an argon-hf etched amorphous copolyester film, such as those described herein, and (D) an argon-hf etched semi-crystalline polyester film, as a counter example. There is a superstructure in the semi-crystalline polyester film that is not apparent in the amorphous copolyester film. Often these superstructures can be seen on the surface of the semi-crystalline polyester film without etching. They are never seen on unetched amorphous PET materials.

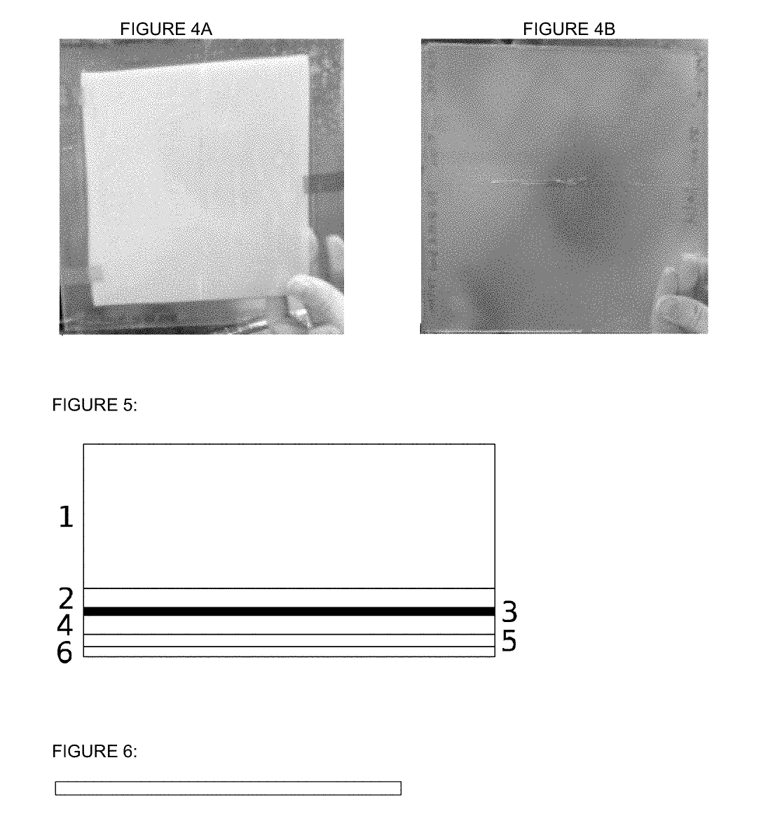

FIGS. 4A and 4B show images of two polyester-based films of equal thickness, after prolonged exposure to heat and moisture (1000 hours of damp heat exposure at 85% humidity and 85° C.). FIG. 4A shows a clear semi-crystalline PET film, which exhibits an extreme amount of hazing, such that it appears white. FIG. 4B shows an amorphous copolyester film, which retained its clarity.

FIG. 5 shows a schematic cross-section of a solar module as described in the invention. The solar module contains a light-receiving side (1), or so-called topside, and a side (5) that is opposite to the light receiving side, which is the backside. Between the top and the backside there is a cell layer comprising an array of interconnected solar cells. The solar cell layer, including its electrical tabbing and bus ribbons, is represented by layer (3). The solar cell layer is encapsulated by one or more encapsulating layers (2) and (4). Instead of two separate layers (2) and (5), a single encapsulating layer may be used which then incorporates the solar cell layer (3). The backside (6) of the solar module is an embodiment of the monolayer backsheet provided herein, which protects the interior of the module from the environment. Between the outer layer of EVA (4), and the monolayer backsheet (6), there is an optional scrim layer (5), as described above.

FIG. 6 shows an embodiment of the monolayer backsheet provided herein. FIG. 6 is a schematic representation of a cross-section of a backsheet as prepared in example 1. It contains an amorphous copolyester film where one face of the film will bond to the encapsulant layer of the solar module (e.g. layer (4) of FIG. 5) if incorporated into a solar module, and the other face will be exposed to the environment.

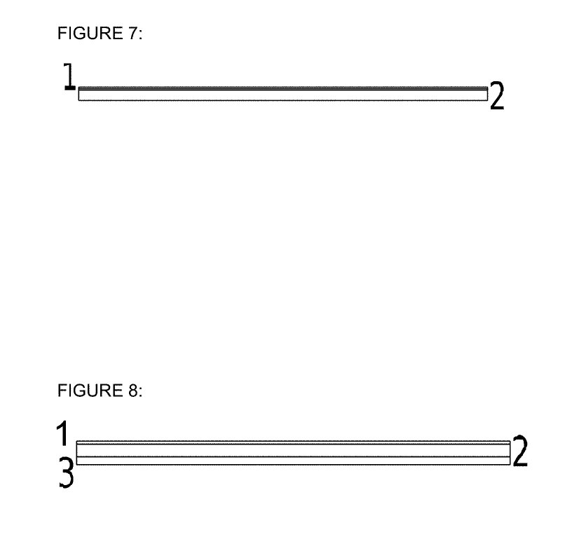

FIG. 7 shows an embodiment of the backsheet provided herein with one optional films adhered to the amorphous copolyester film as described above. FIG. 7 is a schematic representation of a cross-section of a bi-layer backsheet comprising two separate polymer films. Its core layer (2) is an amorphous copolyester film where one face of the film is adhered to the encapsulant layer of the solar module (e.g. layer (4) of FIG. 5) if incorporated into a solar module. The other face of the amorphous copolyester film is adhered to an anti-weathering film (1), which will be exposed to the environment if the backsheet is bonded to a solar module.

FIG. 8 shows an embodiment of the backsheet provided herein with two optional films adhered to the amorphous copolyester film as described above. FIG. 8 is a schematic representation of a cross-section of a tri-layer backsheet comprising three separate polymer films. It core layer (2) is an amorphous copolyester film where one face of the film is adhered to an adhesion promoting PE/EVA copolymer film (3), which will be bonded to the encapsulant layer of the solar module (e.g. layer (4) of FIG. 5) if incorporated into a solar module. The other face of the amorphous copolyester film is adhered to an anti-weathering film (1), which will be exposed to the environment if the backsheet is bonded to a solar module.

The following list of exemplary embodiments illustrates various specific features, advantages, and other details of the invention. The particular materials and amounts recited in these exemplary embodiments, as well as other conditions and details, should not be construed in a manner that would limit the scope of this invention.

### List of Embodiments

1. A monolayer backsheet for solar modules comprising a thermoplastic polymer film, wherein the film contains an amorphous copolyester as the major component, wherein the amorphous copolyester is selected as defined in the claims.

2. The backsheet of 1 wherein the amorphous copolyester film has a thickness of at least 210 or at least 275 μm.

3. The backsheet of any one of 1 to 2 having a dielectric breakdown voltage of at least 8 kV.

4. The backsheet of any one of 1 to 3 wherein the amorphous copolyester film contains UV absorbers.

5. The backsheet of any one of 1 to 4 wherein the amorphous copolyester film contains a colorant, preferably white pigments or reflective materials.

6. The backsheet of any one 1 to 5 wherein the amorphous copolyester film contains a luminescent dye.

7. The backsheet according to any one of 1 to 6 wherein the amorphous copolyester film contains flame-retardants and/or anti dripping agents.

8. The backsheet according to any one of 1 to 7, wherein the amorphous copolyester film has an optional copolymer adhesion-promoting film comprising PE and EVA adhered to one face.

9. The backsheet according to any one of 1 to 8, wherein the amorphous copolyester film has an optional anti-weathering film adhered to one face.

10. A solar module comprising one or more solar cells and one or more encapsulating layer and further comprising a backsheet according to any one of 1 to 9.

11. The solar module of embodiment 10 being a monofacial crystalline solar module.

12. The solar module of embodiment 10 being a bifacial crystalline solar module.

13. The solar module of any one of 10 to 12 wherein the encapsulating layer comprises EVA.

14. Method of making any solar module of embodiment 10 to 13 by vacuum laminating a backsheet of any one of embodiment 1 to 9 to an encapsulating layer of a solar module.

### Example Materials

Tritan GX100 masterbatch, containing UV absorbers, from LTL Infinity Color, PA, United States.

Tritan GX100 masterbatch, containing UV absorbers and Lumogen Red 305 dye, from LTL Infinity Color, PA, United States.

Craneglas® 230 PV Module Glass Scrim from Neenah, Mass., United States.

### Example Embodiments

The following description includes one or more examples according to the invention, which not meant to be exclusionary of any other designs that have been described.

Backsheet Example 1:

The Tritan GX100 master batch, containing UV absorbers, is extruded into a 280 um thick film, forming a clear monolayer backsheet film.

Backsheet Example 2:

Tritan GX100 master batch, containing UV absorbers and Lumogen Red 305 luminescent dye, is extruded into a 280 um thick film, forming a luminescent monolayer backsheet film.

Module Example 3:

The backsheet in Example 1 is laminated in a solar cell module comprising of, from the top layer: low-iron glass, top encapsulant layer, bifacial mono-silicon wafer layer with electrical wiring, optional glass scrim, back encapsulant layer, clear monolayer backsheet. A junction box is adhered to the module where the electrical bus ribbons exit the module.

Module Example 4:

The backsheet in Example 2 is laminated in a solar cell module comprising of, from the top layer: low-iron glass, top encapsulant layer, bifacial mono-silicon wafer layer with electrical wiring, optional glass scrim, back encapsulant layer, luminescent monolayer backsheet. A junction box is adhered to the module where the electrical bus ribbons exit the module.

### Experimental Results:

Superior backsheet performance after simulated environmental exposure.

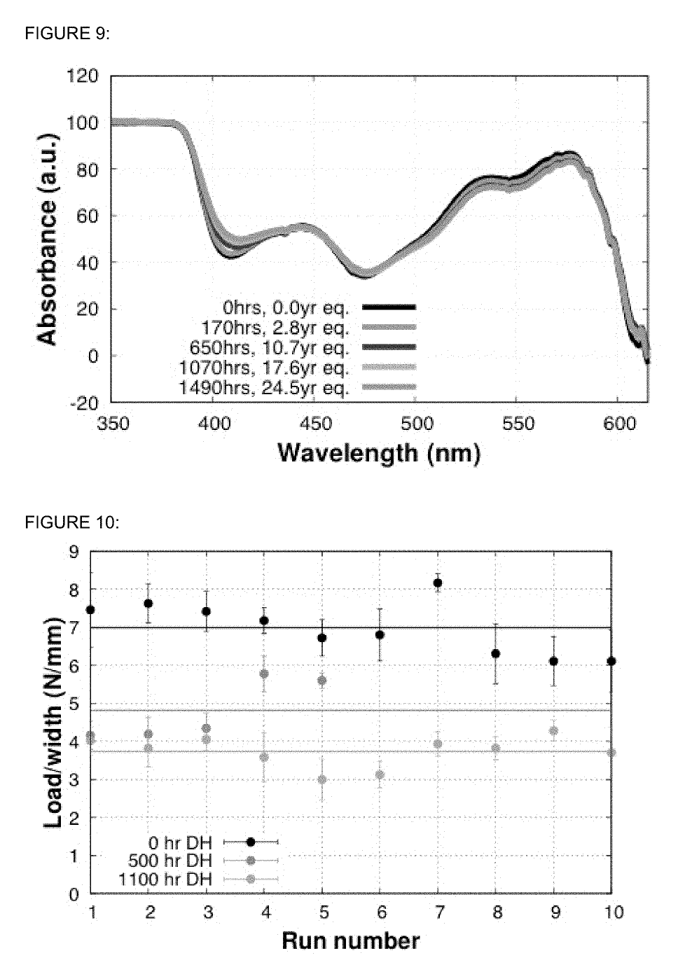

Backsheet Example 2 detailed in the above embodiments was exposed to high intensity UV light for an extended period of time. The absorption spectrum of dye-tinted copolyester shows very little dye degradation or yellowing over 25 years of UV exposure, as shown in FIG. 9.

Backsheet Example 2 detailed in the above embodiments was exposed high heat and humidity for an extended period of time. Adhesion results post damp-heat exposure, 1000 hours 85° C. and 85% humidity, are shown below. The amorphous copolyester film adhesion to EVA was measured by ASTM D903-98 180° peel test, as shown in FIG. 10.

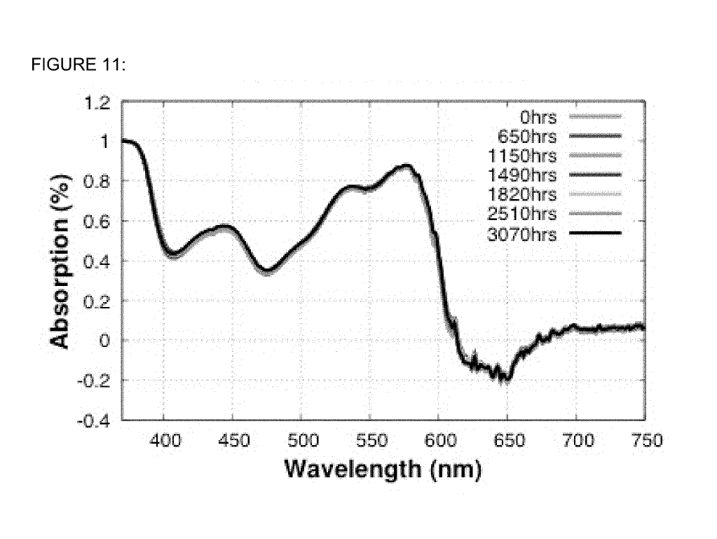

Optical transmission was also measured post damp-heat exposure, as shown in FIG. 11. The copolyester film exhibited excellent resistance to damp heat. There is no spectral change in the film after over 3000 hours of damp heat exposure.

In an example, the present invention provides a film of material for use in a photovoltaic module, e.g., solar module. The material has a thickness characterizing the film of material between 150 microns to 700 microns. The material can be a homogeneous characteristic throughout an entirety of the thickness of the film of material. In an example, the material has a thickness uniformity of +/−50% characterizing the film of material, an amorphous co-polyester composition with a crystallinity below 10% and greater than or equal to 0% with a full width at half maximum (FWHM) of not less than 0.75 degrees and less than 180 degrees, as measured by x-ray diffraction (XRD) in any 1-dimensional cross section of a 2-dimensional crystallographic pattern. The material has a birefringence of the thickness of material that does not exhibit a spherulitic superstructure in a polarizing optical micrographic imaging test, as would a semi-crystalline polyester film. In an example, the material has a spatial region characterizing the film of material having a size of 0.1 meter square or up to 3 square meters. The spatial region can be a surface or backside region. The material has an optical transparency ranging from 80 to 99% total transmittance when the thickness of material is free from a colorant and other additives, a Vicat softening temperature above 85° C., but is less than 160° C., as measured by ASTM D1525 characterizing the thickness of material, a tensile strength at break above 20 MPa and less than 100 MPa as measured by ASTM D882 and an elongation at break of more than 100% and less than 300% as measured by ASTM D882 characterizing the thickness of material, and a dart impact resistance of more than 680 g and less than 1814 g from −30° C. to 23° C. as measured by ASTM 1709A characterizing the thickness of material. In an example, the material has a water vapor transmission rate of less than 12 g/m2·24 hrs and greater than 10-6 g/m2·24 hrs as measured by ASTM F 1249 at 23° C., a partial discharge ranging above 800V and less than 3000V as measured by IEC 60270 in air characterizing the film of material, and a sufficiently low level of brittleness allowing the material to be cut without fracture characterizing the film of material. The material has a mechanical rigidity that allows the thickness of material to be configured in a flat state to be coupled to a photovoltaic layer before a lamination process to adhere the photovoltaic layer with the thickness of material, and compatibility causing the thickness of material to exhibit adhesion to ethylene vinyl acetate (EVA) above 4 N/mm and less than 20 N/mm, measured by ASTM D903-98 180 degree peel test, after the lamination process. Depending upon the example, one or more or all of these features can be included in the material.

In an example, the thickness of material having the homogeneous characteristic is made of an entities selected from at least one of monomers terephthalic acid (TPA) and ethylene glycol (EG), monomers terephthalic acid (TPA) and ethylene glycol (EG) and a secondary diol, cyclohexanedimethanol (CHDM), and

monomer terephthalic acid (TPA), a co-monomer cyclohexanedimethanol (CHDM), and an aliphatic monomer tetramethylcyclobutanediol (TMCD). In an example, the thickness of material further comprises at least one additive selected from a group consisting of a white pigment or a scattering center, including at least one of a titanium dioxide (TiO2), barium sulfate, barium titanate (BaTiO3), strontium titanate (SrTiO3), calcium titanate (CaTiO3), calcium carbonate, lead titanate (PbTiO3), zinc oxide, zinc sulfate, magnesium oxide or aluminum oxide. In an example, the material has a black pigment or an absorbing center, including at least one of a carbon black, iron oxide, complex metal oxide, a metal salt or an organic pigment and a photoluminescent pigment that absorbs light between 300 and 800 nm and emits light between 400 and 900 nm, such as Lumogen® F Red 305. In an example, the material has at least one of the additives selected from a group consisting of a UV absorber, an anti-drip agent, and a flame retardant.

In an example, the thickness of material retains crystallinity less than 10% and greater than or equal to 0% after being stored at 85° C. in 85% RH for 1000 hours. In an example, the thickness of material retains optical transmission of greater than 80% and less than or equal to 100% of its transmission between wavelengths of 400 and 900 nm after being stored at 85° C. in 85% RH for 1000 hours and retains film adhesion to ethylene vinyl acetate (EVA) above 4 N/mm and less than 20 N/mm, measured by ASTM D903-98 180° peel test, after being stored at 85° C. in 85% RH for 1000 hours.

In an example, the thickness of material is substantially free from or has no additional tie layers, a adhesion promoting film, or an anti-weathering film, when coupled to a photovoltaic material as a backsheet for the photovoltaic module.

In an example, the thickness of material is adhered to at least one of a plurality of additional layers selected from a group consisting of a scrim layer adhered to the thickness of material for facilitating a lamination process in manufacture of the photovoltaic module, an additional copolymer film comprising PE and EVA adhered to the thickness of material for increasing an adhesion potential to an encapsulation layer of the photovoltaic module, and an additional film comprising robust polyester or fluoropolymer adhered to the amorphous copolyester film for promoting anti-weathering properties of the thickness of material as a backsheet of the photovoltaic module.

In an example, the invention provides a method of making a photovoltaic module comprising providing a backsheet comprising a thickness of material comprising a thickness characterizing the film of material between 150 microns to 700 microns. The material has a homogeneous characteristic throughout an entirety of the thickness of the film of material, a thickness uniformity of +/−50% characterizing the film of material, an amorphous co-polyester composition

with a crystallinity below 10% and greater than or equal to 0% with a full width at half maximum (FWHM) of not less than 0.75 degrees and less than 180 degrees, as measured by x-ray diffraction (XRD) in any 1-dimensional cross section of a 2-dimensional crystallographic pattern, and has a birefringence of the thickness of material that does not exhibit a spherulitic superstructure in a polarizing optical micrographic imaging test, as would a semi-crystalline polyester film;
a spatial region characterizing the film of material having a size of 0.1 meter square or up to 3 square meters. In an example, the material has an optical transparency ranging from 80 to 99% total transmittance when the thickness of material is free from a colorant and other additives, a Vicat softening temperature above 85° C., but is less than 160° C., as measured by ASTM D1525 characterizing the thickness of material, and a tensile strength at break above 20 MPa and less than 100 MPa as measured by ASTM D882 and an elongation at break of more than 100% and less than 300% as measured by ASTM D882 characterizing the thickness of material. The material has a dart impact resistance of more than 680 g and less than 1814 g from −30° C. to 23° C. as measured by ASTM 1709A characterizing the thickness of material, a water vapor transmission rate of less than 12 g/m2·24 hrs and greater than 10-6 g/m2·24 hrs as measured by ASTM F 1249 at 23° C., and a partial discharge ranging above 800V and less than 3000V as measured by IEC 60270 in air characterizing the film of material;
a sufficiently low level of brittleness allowing the material to be cut without fracture characterizing the film of material. The material has a mechanical rigidity that allows the thickness of material to be configured in a flat state to be coupled to a photovoltaic layer before a lamination process to adhere the photovoltaic layer with the thickness of material, and compatibility causing the thickness of material to exhibit adhesion to ethylene vinyl acetate (EVA) above 4 N/mm and less than 20 N/mm, measured by ASTM D903-98 180 degree peel test, after the lamination process. The method includes coupling the backsheet to a scrim material, a photovoltaic material, and a glass sheet to form a sandwiched structure, such that the scrim material is disposed between the backsheet and the photovoltaic material. The method includes subjecting the sandwiched structure to a vacuum and thermal energy under a lamination process at a temperature above 130° C. and less than 175° C. and causing a texture to be formed onto the backsheet from a Teflon release sheet during a portion of the lamination process.

In an example, the invention provides a photovoltaic module comprising a backsheet material made from a film of material. In an example, the material comprises a thickness characterizing the film of material between 150 microns to 700 microns, a homogeneous characteristic throughout an entirety of the thickness of the film of material, a thickness uniformity of +/−50% characterizing the film of material, an amorphous co-polyester composition with a crystallinity below 10% and greater than or equal to 0%, with a full width at half maximum (FWHM) of not less than 0.75 degrees and less than 180 degrees, as measured by x-ray diffraction (XRD) in any 1-dimensional cross section of a 2-dimensional crystallographic pattern; and having a birefringence of the thickness of material that does not exhibit a spherulitic superstructure in a polarizing optical micrographic imaging test, as would a semi-crystalline polyester film, a spatial region characterizing the film of material having a size of 0.1 meter square or up to 3 square meters, an optical transparency ranging from 80 to 99% total transmittance when the thickness of material is free from a colorant and other additives, a Vicat softening temperature above 85° C., but is less than 160° C., as measured by ASTM D1525 characterizing the thickness of material, a tensile strength at break above 20 MPa and less than 100 MPa as measured by ASTM D882 and an elongation at break of more than 100% and less than 300% as measured by ASTM D882 characterizing the thickness of material, a dart impact resistance of more than 680 g and less than 1814 g from −30° C. to 23° C. as measured by ASTM 1709A characterizing the thickness of material, a water vapor transmission rate of less than 12 g/m2·24 hrs and greater than 10-6 g/m2·24 hrs as measured by ASTM F 1249 at 23° C., a partial discharge ranging above 800V and less than 3000V as measured by IEC 60270 in air characterizing the film of material, a sufficiently low level of brittleness allowing the material to be cut without fracture characterizing the film of material, and

a mechanical rigidity that allows the thickness of material to be configured in a flat state to be coupled to a photovoltaic layer before a lamination process to adhere the photovoltaic layer with the thickness of material, and compatibility causing the thickness of material to exhibit adhesion to ethylene vinyl acetate (EVA) above 4 N/mm and less than 20 N/mm, measured by ASTM D903-98 180 degree peel test, after the lamination process. The thickness of material is adhered to at least one of a plurality of additional layers selected from a group consisting of a scrim layer adhered to the thickness of material for facilitating a lamination process in manufacture of the photovoltaic module; an additional copolymer film comprising PE and EVA adhered to the thickness of material for increasing an adhesion potential to an encapsulation layer of the photovoltaic module; and an additional film comprising robust polyester or fluoropolymer adhered to the amorphous copolyester film for promoting anti-weathering properties of the thickness of material as a backsheet of the photovoltaic module.

In an example, the thickness of material having the homogeneous characteristic is made of an entities selected from at least one of monomers terephthalic acid (TPA) and ethylene glycol (EG),

monomers terephthalic acid (TPA) and ethylene glycol (EG) and a secondary diol, cyclohexanedimethanol (CHDM), and
monomer terephthalic acid (TPA), a co-monomer cyclohexanedimethanol (CHDM), and an aliphatic monomer tetramethylcyclobutanediol (TMCD).

In an example, the thickness of material further comprises at least one additive selected from a group consisting of

a white pigment or a scattering center, including at least one of a titanium dioxide (TiO2), barium sulfate, barium titanate (BaTiO3), strontium titanate (SrTiO3), calcium titanate (CaTiO3), calcium carbonate, lead titanate (PbTiO3), zinc oxide, zinc sulfate, magnesium oxide or aluminum oxide;
a black pigment or an absorbing center, including at least one of a carbon black, iron oxide, complex metal oxide;
a metal salt or an organic pigment; and
a photoluminescent pigment that absorbs light between 300 and 800 nm and emits light between 400 and 900 nm, such as Lumogen® F Red 305;
at least one of the additives selected from a group consisting of a UV absorber, an anti-drip agent, and a flame retardant.

In an example, the thickness of material

retains crystallinity less than 10% and greater than or equal to 0% a after being stored at 85° C. in 85% RH for 1000 hours;
retains optical transmission of greater than 80% and less than or equal to 100% of its transmission between wavelengths of 400 and 900 nm after being stored at 85° C. in 85% RH for 1000 hours; and
retains film adhesion to ethylene vinyl acetate (EVA) above 3 N/mm and less than 20 N/mm, measured by ASTM D903-98 180° peel test, after being stored at 85° C. in 85% RH for 1000 hours.

In an example, the thickness of material is substantially free from or has no additional tie layers, a adhesion promoting film, or an anti-weathering film, when coupled to the photovoltaic material as the backsheet for the photovoltaic module.

In an example, the invention provides a film of material for use in a photovoltaic module, the material has any of the aforementioned characteristics, alone or in combination.

### REFERENCES

1. Zhou, H., Lofgren, E. A., & Jabarin, S. A. (2009). Effects of microcrystallinity and morphology on physical aging and its associated effects on tensile mechanical and environmental stress cracking properties of poly(ethylene terephthalate). Journal of Applied Polymer Science J. Appl. Polym. Sci., 112(5), 2906-2917.
2. Zia, Qamer, Elisabeth Ingoli\check{c}, and Rene Androsch. “Surface and Bulk Morphology of Cold-crystallized Poly(ethylene Terephthalate).” Colloid Polym Sci Colloid and Polymer Science 288.7 (2010): 819-25.

The list of exemplary embodiments illustrates various specific features, advantages, and other details of the invention. The particular materials and amounts recited in these exemplary embodiments, as well as other conditions and details, should not be construed in a manner that would limit the scope of this invention. In an example, any one of the features or elements can be combined with others or separated, without departing from the scope of the claims herein.

The invention claimed is:

1. A film of material for use in a photovoltaic module, the material comprising:
a thickness characterizing the film of material between 150 microns to 700 microns;
a homogeneous characteristic throughout an entirety of the thickness of the film of material;
a thickness uniformity of +/−50% characterizing the film of material;
an amorphous co-polyester composition:
with a crystallinity below 10% and greater than or equal to 0%;
with a full width at half maximum (FWHM) of not less than 0.75 degrees and less than 180 degrees, as measured by x-ray diffraction (XRD) in any 1-dimensional cross section of a 2-dimensional crystallographic pattern; and having a birefringence of the thickness of material that does not exhibit a spherulitic superstructure in a polarizing optical micrographic imaging test, as would a semi-crystalline polyester film;
a spatial region characterizing the film of material having a size of 0.1 meter square or up to 3 square meters;
an optical transparency ranging from 80 to 99% total transmittance when the thickness of material is free from a colorant and other additives;
a Vicat softening temperature above 85° C., but is less than 160° C., as measured by ASTM D1525 characterizing the thickness of material;
a tensile strength at break above 20 MPa and less than 100 MPa as measured by ASTM D882 and an elongation at break of more than 100% and less than 300% as measured by ASTM D882 characterizing the thickness of material;
a dart impact resistance of more than 680 g and less than 1814 g from −30° C. to 23° C. as measured by ASTM 1709A characterizing the thickness of material;
a water vapor transmission rate of less than 12 g/m²·24 hrs and greater than 10⁻⁶ g/m²·24 hrs as measured by ASTM F 1249 at 23° C.;
a partial discharge ranging above 800V and less than 3000V as measured by IEC 60270 in air characterizing the film of material;
a sufficiently low level of brittleness allowing the material to be cut without fracture characterizing the film of material; and
a mechanical rigidity that allows the thickness of material to be configured in a flat state to be coupled to a photovoltaic layer before a lamination process to adhere the photovoltaic layer with the thickness of material, and compatibility causing the thickness of material to exhibit adhesion to ethylene vinyl acetate (EVA) above 4 N/mm and less than 20 N/mm, measured by ASTM D903-98 180 degree peel test, after the lamination process.

2. The film according to claim 1, wherein the thickness of material having the homogeneous characteristic is made of an entities selected from at least one of monomers terephthalic acid (TPA) and ethylene glycol (EG),
monomers terephthalic acid (TPA) and ethylene glycol (EG) and a secondary diol, cyclohexanedimethanol (CHDM), and
monomer terephthalic acid (TPA), a co-monomer cyclohexanedimethanol (CHDM), and an aliphatic monomer tetramethylcyclobutanediol (TMCD).

3. The film according to claim 1, wherein the thickness of material further comprises at least one additive selected from a group consisting of:
a white pigment or a scattering center, including at least one of a titanium dioxide (TiO₂), barium sulfate, barium titanate (BaTiO₃), strontium titanate (SrTiO₃), calcium titanate (CaTiO₃), calcium carbonate, lead titanate (PbTiO₃), zinc oxide, zinc sulfate, magnesium oxide or aluminum oxide;
a black pigment or an absorbing center, including at least one of a carbon black, iron oxide, complex metal oxide;
a metal salt or an organic pigment; and
a photoluminescent pigment that absorbs light between 300 and 800 nm and emits light between 400 and 900 nm, such as Lumogen® F Red 305;
at least one of the additives selected from a group consisting of a UV absorber, an anti-drip agent, and a flame retardant.

4. The film according to claim 1, wherein the thickness of material
retains crystallinity less than 10% and greater than or equal to 0% after being stored at 85° C. in 85% RH for 1000 hours;
retains optical transmission of greater than 80% and less than or equal to 100% of its transmission between wavelengths of 400 and 900 nm after being stored at 85° C. in 85% RH for 1000 hours; and
retains film adhesion to ethylene vinyl acetate (EVA) above 4 N/mm and less than 20 N/mm, measured by ASTM D903-98 180° peel test, after being stored at 85° C. in 85% RH for 1000 hours.

5. The film according to claim 1, wherein the thickness of material is substantially free from or has no additional tie layers, a adhesion promoting film, or an anti-weathering film, when coupled to a photovoltaic material as a backsheet for the photovoltaic module.

6. The film of according to claim 1, wherein the thickness of material is adhered to at least one of a plurality of additional layers selected from a group consisting of:
a scrim layer adhered to the thickness of material for facilitating a lamination process in manufacture of the photovoltaic module;
an additional copolymer film comprising PE and EVA adhered to the thickness of material for increasing an adhesion potential to an encapsulation layer of the photovoltaic module; and
an additional film comprising robust polyester or fluoropolymer adhered to the amorphous copolyester film for promoting anti-weathering properties of the thickness of material as a backsheet of the photovoltaic module.

7. A method of making a photovoltaic module comprising:
providing a backsheet comprising a thickness of material comprising:
a thickness characterizing the film of material between 150 microns to 700 microns;
a homogeneous characteristic throughout an entirety of the thickness of the film of material;
a thickness uniformity of +/−50% characterizing the film of material;
an amorphous co-polyester composition:
with a crystallinity below 10% and greater than or equal to 0%;
with a full width at half maximum (FWHM) of not less than 0.75 degrees and less than 180 degrees, as measured by x-ray diffraction (XRD) in any 1-dimensional cross section of a 2-dimensional crystallographic pattern; and having a birefringence of the thickness of material that does not exhibit a spherulitic superstructure in a polarizing optical micrographic imaging test, as would a semi-crystalline polyester film;
a spatial region characterizing the film of material having a size of 0.1 meter square or up to 3 square meters;
an optical transparency ranging from 80 to 99% total transmittance when the thickness of material is free from a colorant and other additives;
a Vicat softening temperature above 85° C., but is less than 160° C., as measured by ASTM D1525 characterizing the thickness of material;
a tensile strength at break above 20 MPa and less than 100 MPa as measured by ASTM D882 and an elongation at break of more than 100% and less than 300% as measured by ASTM D882 characterizing the thickness of material;
a dart impact resistance of more than 680 g and less than 1814 g from −30° C. to 23° C. as measured by ASTM 1709A characterizing the thickness of material;
a water vapor transmission rate of less than 12 g/m²·24 hrs and greater than 10⁶ g/m²·24 hrs as measured by ASTM F 1249 at 23° C.;
a partial discharge ranging above 800V and less than 3000V as measured by IEC 60270 in air characterizing the film of material;
a sufficiently low level of brittleness allowing the material to be cut without fracture characterizing the film of material; and
a mechanical rigidity that allows the thickness of material to be configured in a flat state to be coupled to a photovoltaic layer before a lamination process to adhere the photovoltaic layer with the thickness of material, and compatibility causing the thickness of material to exhibit adhesion to ethylene vinyl acetate (EVA) above 4 N/mm and less than 20 N/mm, measured by ASTM D903-98 180 degree peel test, after the lamination process;
coupling the backsheet to a scrim material, a photovoltaic material, and a glass sheet to form a sandwiched structure, such that the scrim material is disposed between the backsheet and the photovoltaic material;
subjecting the sandwiched structure to a vacuum and thermal energy under a lamination process at a temperature above 130° C. and less than 175° C.; and
causing a texture to be formed onto the backsheet from a Teflon release sheet during a portion of the lamination process.

8. A photovoltaic module comprising:
a backsheet material made from a film of material, the material comprising:
a thickness characterizing the film of material between 150 microns to 700 microns;
a homogeneous characteristic throughout an entirety of the thickness of the film of material;
a thickness uniformity of +/−50% characterizing the film of material;
an amorphous co-polyester composition:
with a crystallinity below 10% and greater than or equal to 0%;
with a full width at half maximum (FWHM) of not less than 0.75 degrees and less than 180 degrees, as measured by x-ray diffraction (XRD) in any 1-dimensional cross section of a 2-dimensional crystallographic pattern; and having a birefringence of the thickness of material that does not exhibit a spherulitic superstructure in a polarizing optical micrographic imaging test, as would a semi-crystalline polyester film;
a spatial region characterizing the film of material having a size of 0.1 meter square or up to 3 square meters;
an optical transparency ranging from 80 to 99% total transmittance when the thickness of material is free from a colorant and other additives;
a Vicat softening temperature above 85° C., but is less than 160° C., as measured by ASTM D1525 characterizing the thickness of material;
a tensile strength at break above 20 MPa and less than 100 MPa as measured by ASTM D882 and an elongation at break of more than 100% and less than 300% as measured by ASTM D882 characterizing the thickness of material;
a dart impact resistance of more than 680 g and less than 1814 g from −30° C. to 23° C. as measured by ASTM 1709A characterizing the thickness of material;
a water vapor transmission rate of less than 12 g/m²·24 hrs and greater than 10⁻⁶ g/m²·24 hrs as measured by ASTM F 1249 at 23° C.;
a partial discharge ranging above 800V and less than 3000V as measured by IEC 60270 in air characterizing the film of material;
a sufficiently low level of brittleness allowing the material to be cut without fracture characterizing the film of material; and
a mechanical rigidity that allows the thickness of material to be configured in a flat state to be coupled to a photovoltaic layer before a lamination process to adhere the photovoltaic layer with the thickness of material, and compatibility causing the thickness of material to exhibit adhesion to ethylene vinyl acetate (EVA) above 4 N/mm and less than 20 N/mm, measured by ASTM D903-98 180 degree peel test, after the lamination process;
wherein the thickness of material is adhered to at least one of a plurality of additional layers selected from a group consisting of a scrim layer adhered to the thickness of material for facilitating a lamination process in manufacture of the photovoltaic module; an additional copolymer film comprising PE and EVA adhered to the thickness of material for increasing an adhesion potential to an encapsulation layer of the photovoltaic module; and an additional film comprising robust polyester or fluoropolymer adhered to the amorphous copolyester film for promoting anti-weathering properties of the thickness of material as a backsheet of the photovoltaic module.

9. The film according to claim 8, wherein the thickness of material having the homogeneous characteristic is made of an entities selected from at least one of monomers terephthalic acid (TPA) and ethylene glycol (EG),
monomers terephthalic acid (TPA) and ethylene glycol (EG) and a secondary diol, cyclohexanedimethanol (CHDM), and
monomer terephthalic acid (TPA), a co-monomer cyclohexanedimethanol (CHDM), and an aliphatic monomer tetramethylcyclobutanediol (TMCD).

10. The film according to claim 8, wherein the thickness of material further comprises at least one additive selected from a group consisting of:
a white pigment or a scattering center, including at least one of a titanium dioxide (TiO₂), barium sulfate, barium titanate (BaTiO₃), strontium titanate (SrTiO₃), calcium titanate (CaTiO₃), calcium carbonate, lead titanate (PbTiO₃), zinc oxide, zinc sulfate, magnesium oxide or aluminum oxide;
a black pigment or an absorbing center, including at least one of a carbon black, iron oxide, complex metal oxide;
a metal salt or an organic pigment; and
a photoluminescent pigment that absorbs light between 300 and 800 nm and emits light between 400 and 900 nm, such as Lumogen® F Red 305;
at least one of the additives selected from a group consisting of a UV absorber, an anti-drip agent, and a flame retardant.

11. The film according to claim 8, wherein the thickness of material
retains crystallinity less than 10% and greater than or equal to 0% after being stored at 85° C. in 85% RH for 1000 hours;
retains optical transmission of greater than 80% and less than or equal to 100% of its transmission between wavelengths of 400 and 900 nm after being stored at 85° C. in 85% RH for 1000 hours; and
retains film adhesion to ethylene vinyl acetate (EVA) above 3 N/mm and less than 20 N/mm, measured by ASTM D903-98 180° peel test, after being stored at 85° C. in 85% RH for 1000 hours.

12. The film according to claim 8, wherein the thickness of material is substantially free from or has no additional tie layers, a adhesion promoting film, or an anti-weathering film, when coupled to the photovoltaic material as the backsheet for the photovoltaic module.

13. A film of material for use in a photovoltaic module, the material comprising:
a thickness characterizing the film of material between 150 microns to 700 microns;
a homogeneous characteristic throughout an entirety of the thickness of the film of material;
a thickness uniformity of +/−50% characterizing the film of material;
an amorphous co-polyester composition:
with a crystallinity below 10% and greater than or equal to 0%;
with a full width at half maximum (FWHM) of not less than 0.75 degrees and less than 180 degrees, as measured by x-ray diffraction (XRD) in any 1-dimensional cross section of a 2-dimensional crystallographic pattern; and having a birefringence of the thickness of material that does not exhibit a spherulitic superstructure in a polarizing optical micrographic imaging test, as would a semi-crystalline polyester film;
a spatial region characterizing the film of material having a size of 0.1 meter square or up to 3 square meters;
an optical transparency ranging from 80 to 99% total transmittance when the thickness of material is free from a colorant and other additives;
a Vicat softening temperature above 85° C., but is less than 160° C., as measured by ASTM D1525 characterizing the thickness of material;
a tensile strength at break above 20 MPa and less than 100 MPa as measured by ASTM D882 and an elongation at break of more than 100% and less than 300% as measured by ASTM D882 characterizing the thickness of material;
a dart impact resistance of more than 680 g and less than 1814 g from −30° C. to 23° C. as measured by ASTM 1709A characterizing the thickness of material;
a water vapor transmission rate of less than 12 g/m²·24 hrs and greater than 10⁻⁶ g/m²·24 hrs as measured by ASTM F 1249 at 23° C.;
a partial discharge ranging above 800V and less than 3000V as measured by IEC 60270 in air characterizing the film of material;
a sufficiently low level of brittleness allowing the material to be cut without fracture characterizing the film of material; and
a mechanical rigidity that allows the thickness of material to be configured in a flat state to be coupled to a photovoltaic layer before a lamination process to adhere the photovoltaic layer with the thickness of material, and compatibility causing the thickness of material to exhibit adhesion to ethylene vinyl acetate (EVA) above 3 N/mm and less than 20 N/mm, measured by ASTM D903-98 180 degree peel test, after the lamination process; and
wherein the thickness of material having the homogeneous characteristic is made of an entities selected from at least one of monomers terephthalic acid (TPA) and ethylene glycol (EG),
monomers terephthalic acid (TPA) and ethylene glycol (EG) and a secondary diol, cyclohexanedimethanol (CHDM), and
monomer terephthalic acid (TPA), a co-monomer cyclohexanedimethanol (CHDM), and an aliphatic monomer tetramethylcyclobutanediol (TMCD).

14. The film according to claim 13, wherein the thickness of material further comprises at least one additive selected from a group consisting of:
a white pigment or a scattering center, including at least one of a titanium dioxide (TiO₂), barium sulfate, barium titanate (BaTiO₃), strontium titanate (SrTiO₃), calcium titanate (CaTiO₃), calcium carbonate, lead titanate (PbTiO₃), zinc oxide, zinc sulfate, magnesium oxide or aluminum oxide;
a black pigment or an absorbing center, including at least one of a carbon black, iron oxide, complex metal oxide;
a metal salt or an organic pigment; and
a photoluminescent pigment that absorbs light between 300 and 800 nm and emits light between 400 and 900 nm, such as Lumogen® F Red 305;
at least one of the additives selected from a group consisting of a UV absorber, an anti-drip agent, and a flame retardant.

15. The film according to claim 13, wherein the thickness of material
retains crystallinity less than 10% and greater than or equal to 0% after being stored at 85° C. in 85% RH for 1000 hours;
retains optical transmission of greater than 80% and less than or equal to 100% of its transmission between wavelengths of 400 and 900 nm after being stored at 85° C. in 85% RH for 1000 hours; and
retains film adhesion to ethylene vinyl acetate (EVA) above 3 N/mm and less than 20 N/mm, measured by ASTM D903-98 180° peel test, after being stored at 85° C. in 85% RH for 1000 hours.

16. The film according to claim 13, wherein the thickness of material is substantially free from or has no additional tie layers, a adhesion promoting film, or an anti-weathering film, when coupled to a photovoltaic material as a backsheet for the photovoltaic module.

17. The film of according to claim 13, wherein the thickness of material is adhered to at least one of a plurality of additional layers selected from a group consisting of:
a scrim layer adhered to the thickness of material for facilitating a lamination process in manufacture of the photovoltaic module;
an additional copolymer film comprising PE and EVA adhered to the thickness of material for increasing an adhesion potential to an encapsulation layer of the photovoltaic module; and
an additional film comprising robust polyester or fluoropolymer adhered to the amorphous copolyester film for promoting anti-weathering properties of the thickness of material as a backsheet of the photovoltaic module.
